(19) United States
(12) Patent Application Publication
(10) Pub. No.: US 2002/0050939 A1
(43) Pub. Date: May 2, 2002

(54) Apparatus and method for an encoder interface module

(76) Inventor: Zhenyu Yu, Sugar Land, TX (US)

Correspondence Address: TEXAS INSTRUMENTS INCORPORATED, P O BOX 655474, M/S 3999, DALLAS, TX, 75265

(21) Appl. No.: 09/904,242

(22) Filed: Jul. 12, 2001

Related U.S. Application Data
(60) Provisional application No. 60/245,656, filed on Nov. 2, 2000.
(60) Provisional application No. 60/255,253, filed on Dec. 13, 2000.
(60) Provisional application No. 60/267,589, filed on Feb. 9, 2001.

(51) Int. Cl. H03M 1/12

(52) U.S. Cl. 341/155

(57) ABSTRACT

In a processing system having a central processing unit and a plurality of modules units for receiving signals from encoder/sensor units, an encoder interface module can count the pulses in an incoming signal train. The encoder interface module has a plurality of registers and a compare unit for the generation of flags when the number of counted pulses has a predetermined relationship with numeric values stored in the registers. The encoder interface unit has apparatus for exchanging signal groups with an inter-module network. The inter-module network permits signal groups to be exchanged between interface modules without intervention of the central processing unit. The exchanged signal groups can coordinate the activity of the encoder modules.

This application claims the benefit of U.S. Provisional Application No. 60/245,656 filed Nov, 2, 2000; U.S. Provisional Application No. 60/255,253 filed Dec. 13, 2000; and U.S. Provisional Application No. 60/267,589 filed Feb. 9, 2001.

### CROSS REFERENCE TO RELATED APPLICATIONS

U.S. patent application No. (Attorney Docket TI-32610) entitled “APPARATUS AND METHOD FOR PERIPHERAL INTER-MODULE EVENT COMMUNICATION SYSTEM”, invented by Zhenyu Yu, filed on even date herewith, and assigned to the assignee of the present application; and U.S. patent application No. (Attorney Docket TI-32332) entitled “APPARATUS AND METHOD FOR A SIGNAL TRANSISITON CAPTURE MOULE”, invented by Zhenyu Yu, filed on even date herewith, and assigned to the assignee of the present application are related applications.

### BACKGROUND OF THE INVENTION

1. Field of the Invention

This invention relates generally to digital signal processor systems and, more particularly, to digital signal processor systems having a plurality of peripheral modules coupled thereto. The peripheral modules include an encoder interface module, a module that receives signals from a sensor/encoder element.

2. Background of the Invention

The digital signal processor has proven to be well suited for implementing data processing system that monitor activity of external devices. In response to the data acquired from the external devices by means of encoder peripheral devices, appropriate status/event signals can be derived and, based on the status/event signals, control signals can be generated to control the operation of the external devices. Generally, the input signals to the encoder modules are at least one train of pulses. For example, the encoder peripheral devices can respond to signals resulting from rotation of a shaft.

Referring to FIG. 1A, a processing system 1 for monitoring and controlling the activity of an external component 3 is shown. The processing system 1 includes a central processing unit 10, typically a digital signal processor core, and a peripheral device bus 5. Coupled to the peripheral device bus 5 are, for example, a memory unit 12, a serial communication interface (SCI) unit 13, a serial peripheral interface (SPI) unit 14, a multi-channel buffered serial port 15, an analog-to-digital converter (ADC) module 16, an encoder interface module 17, an event manager module 18, and a signal transition event capture module 19. The analog to digital module 16, the encoder interface module 17, the event manager module 18 and the signal transition capture module 19 receive signals from sensor units monitoring the external component 3. The event manager module 18 applies (control) signals to the component device 3.

The memory unit 12 provides for storage of data signal groups required by or generated by, the central processing unit 10. The serial interface communication unit 13, the serial peripheral interface unit 14, and the multi-channel serial buffer unit 15 are interface modules that permit exchange of signals with other processing, communication, and display units (not shown). The analog to digital converter module 16 receives signals from a sensor unit in an analog format and converts these signals to a digital format for processing by the central processing unit 10. The encoder interface module 17 receives and processes signals from an encoder unit. The encoder interface module 17 has at least one group of signals applied thereto that is typically in the form of a series of pulses. For example, the series of pulses can provide timing and direction signals from an encoder unit monitoring a rotating shaft. The encoder interface unit 17 provides position and speed information about a monitored shaft rotation. The event manager module 18, according to one embodiment, can include a timer (or timers), compare unit(s) and other interface components. The event manager module 18 provides, among other activities, control signals to the external device 3 based on commands received from the central processing unit 10. The signal transition capture module 19 provides apparatus for associating preselected transition/events in the external apparatus with a time designation or time stamp.

Referring to FIG. 1B, an example of an external device 7 to which the interface modules can be advantageously coupled. The external device is a three-phase motor 75. The three-phase motor 75 is energized by an alternating voltage source that is applied to input terminals of rectifier 71. Coupled across the output terminals of rectifier 71 are a capacitor 72 and three pairs of power transistors 73A and 73B, 73C and 73D, and 73E and 73F, coupled in series. Each of the pairs of power transistors 73A and 73B, 73C and 73D, and 73E and 73F is coupled to the one of the three energizing coils of the motor. Hall effect sensors 76 associated with the motor 75 generate a series of pulses related to the rotation of the rotor of motor 75. These signals are applied to signal transition capture module 19. The current in the individual coils of the three-phase motor 71 can be monitored by current sensors 74A, 74B, and 74C. The signals from the current sensors 74A, 74B, and 74C are coupled through isolation element 81 to input terminals of the analog to digital convert module 16. Alternatively, the current can be monitored by resistances 731, 732, and 733 coupled in series with each of the power transistor pairs transistors 73A and 73B, 73C and 73D, and 73E and 73F, respectively. The voltages across these resistances 731, 732, and 733 can be applied to the analog to digital converter module 16. When the voltages across the resistances 731, 732 and 733 are sampled when the coupled power transistor (of the pair of power transistors) is conducting, an approximation of the current through the motor winding for each phase can be obtained. An optical encoder sensor 79 can optically monitor the rotation of the shaft (rotor) 751 of motor 75. Typically, the output signals of the optical encoder 79 are a first series of pulses related to the rotational speed of the motor shaft and a second series of pulses defining the direction of the rotation. The signals from the optical encoder are applied to encoder interface module 17. The control signals applied to the base terminals of the power transistor pairs 73A and 73B, 73C and 73D, and 73E and 73F originate in event manager unit 18 and are applied, through driver circuits 77.

While the foregoing processing system 1 can acquire signals from an external component and provide status and control information, greater flexibility in the system is desirable. In particular, inter-module communication has proven necessary for coordinating activity of the modules. For example, a specific device parameter identified by the encoder interface module can be the event that triggers the activation of the analog to digital converter module 16. In the prior art, to activate the analog to digital converter module 16 based on a parameter identified by the encoder interface module 17, the central processing unit would have to interact with the encoder interface module 17 by means of the device peripheral bus 5. The central processing unit would then determine whether a certain condition or conditions had been fulfilled. The central processing unit 10 would then have to interact with the analog to digital converter module 16 by the device peripheral bus 5 to begin operation of the analog to digital converter module 16. The involvement of the central processing unit 10 and the device peripheral bus 5 increases the complexity of the system. Appropriate protocols must be added to the system to accomplish the communication between the encoder interface module 17 and the central processing system, and the central processing system and the analog to digital converter module 16. Because the device peripheral bus 5 is used in the communication between modules, the communication can be delayed if the device peripheral bus 5 is engaged in a higher priority activity.

In addition, one of the modules, the encoder interface module 17, has a relatively limited functionality. Typically, the encoder interface module 17 can count the number of pulses produced by the encoder unit. The total number of pulses is a direct indication of the angular position of the monitored motor shaft. From the number of pulses during a predetermined period of time, the angular (rotational) velocity of the monitored shaft can be determined. Typically, the (quadrature) encoder provides an additional pulse stream that is phase-shifted 90° with respect to the first pulse stream. This added pulse stream permits the direction of rotation to be determined. The angular position and/or the rotational velocity of the shaft are communicated to a central processing unit. Using the data from the encoder interface unit, the central processing unit can determine additional parameters, such as whether the angular position or the rotational velocity are beyond prescribed limits, and can generate control signals governing the operation of the shaft. Such a procedure, in addition to utilizing the device peripheral bus 5 excessively, requires the central processing unit to interrupt other processing tasks to obtain measured parameters of sequence of pulses and to compare the measured parameters with preselected values. In addition, a trigger event for initiating the determination of the rotational velocity must be applied to the encoder interface unit.

A need has therefore been felt for apparatus and an associated method having the feature, in a processing system having an encoder interface module receiving signals from sensor/encoder devices, that the encoder interface modules can determine device parameters from a series of pulses. It would be yet another feature of the apparatus and associated method to compare the device parameters with preselected values. It would be another feature of the apparatus and associated method to generate flags when the measured device parameters have a predefined relationship with preselected values. It would yet be another feature of the apparatus and associated method that the encoder interface module can receive signals from and apply signals to the associated modules without the intervention of the central processing unit.

### SUMMARY OF THE INVENTION

The aforementioned and other features are accomplished, according to the present invention, by providing an encoder interface module responsive to a series of pulses from an encoder unit. The encoder interface module includes apparatus for determination, from the encoder unit pulse trains, the direction of the rotation of a motor shaft. The encoder interface module includes a clock formation unit. The frequency of the clock signal provided by the clock formation unit is directly related to the velocity of rotation of the motor shaft. The encoder interface module includes a counter for counting according to the determined direction and the clock signal. The encoder interface module further includes a plurality of registers including a period register, an initialization, a sampling latch, reset latch, and a compare register. The encoder interface unit also includes a compare unit whereby the content of the counter unit can be compared to the contents of selected registers or can be compared to the zero value. The result of the comparison is the generation of flags that can be used to signal to the central processing unit of a predetermined relationship between the device parameters and values stored the registers is identified. The encoder interface module can also receive selected signals, such as flags, from other modules without intervention of the central processing unit and can apply selected signals to other interface modules without intervention of the central processing unit.

### DESCRIPTION OF THE DRAWINGS

FIG. 1A is a block diagram of a processing system having a plurality of modules receiving signals from an external component according to the prior art, while FIG. 1B is an example of an external device to which the interface modules of the present invention can be coupled.

FIG. 2 is a block diagram of a processing system having a plurality of modules receiving signals from and applying signals to an external component and providing for inter-module communication according to the present invention.

FIG. 3 is a simple embodiment for the inter-module distribution of the interface module signals according to the present invention.

FIG. 4 illustrates a second embodiment of the present invention that provides for inter-module transfer of interface module signals.

FIG. 5 is a block diagram of the encoder interface unit according to the present invention.

### DESCRIPTION OF THE PREFERRED EMBODIMENTS

1 Detailed Description of the Figures

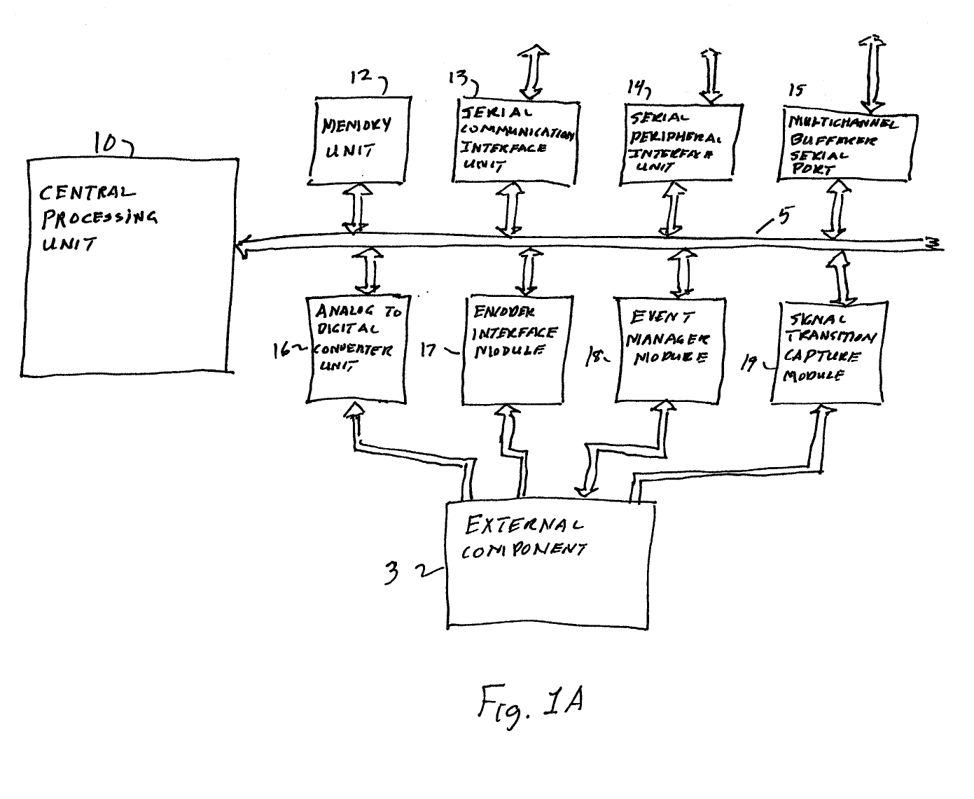

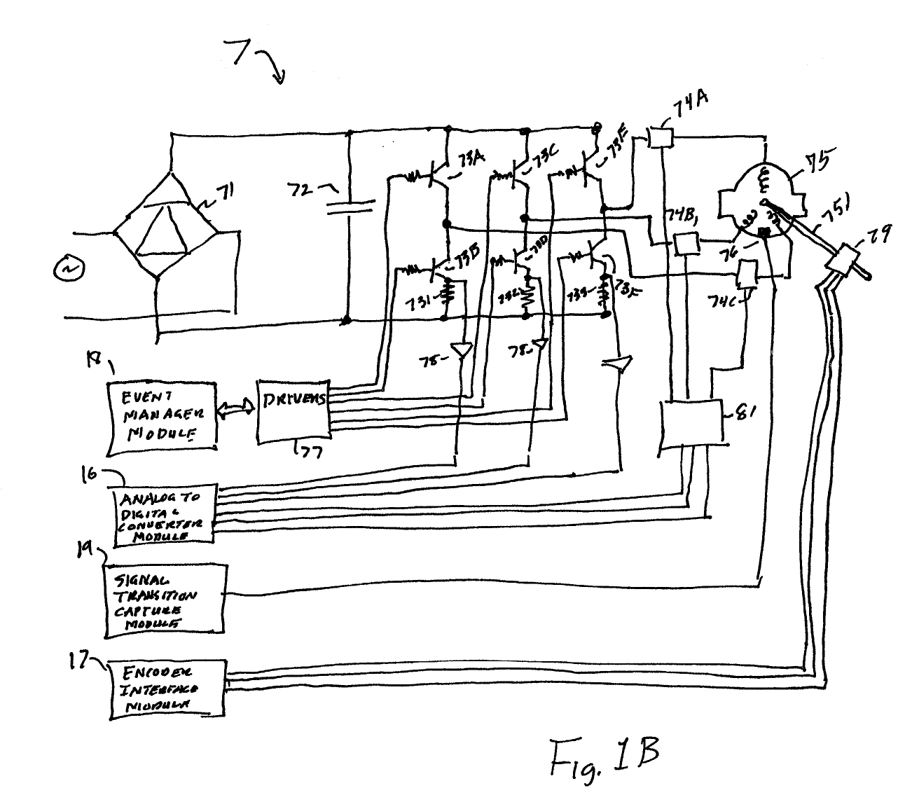

FIG. 1A and FIG. 1B has been described with respect to the related art.

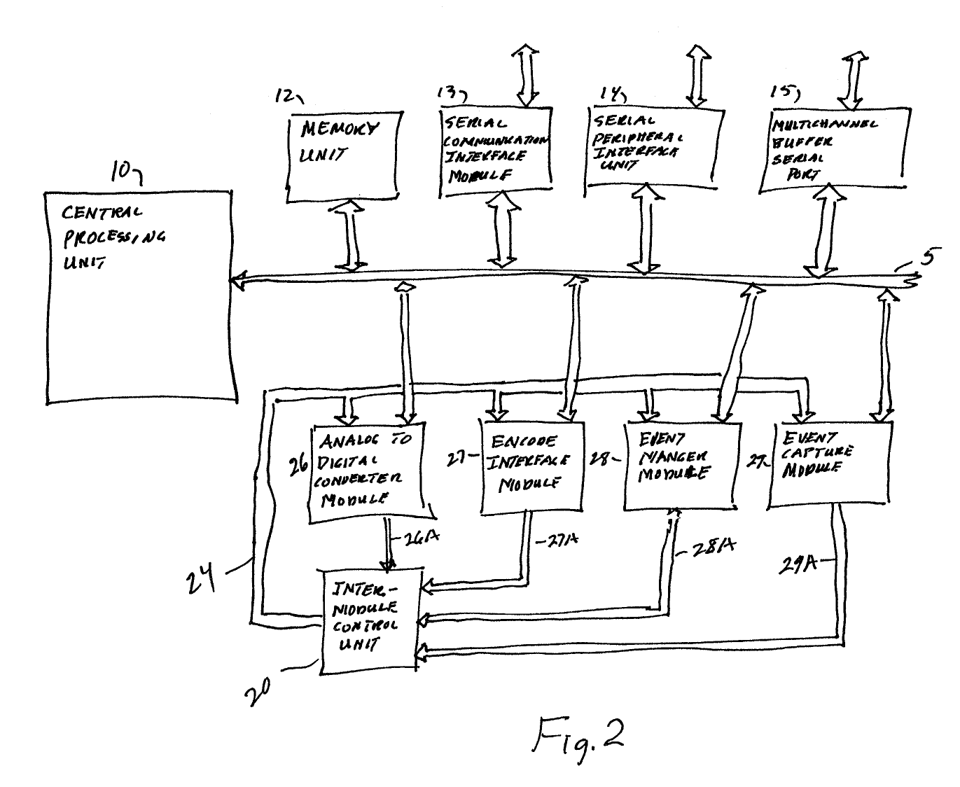

Referring to FIG. 2, a block diagram of the event/signal processing system of FIG. 1 with the apparatus for inter-module communication, according to the present invention, is shown. The central processing unit 10, the device peripheral bus 5, the memory unit 12, the serial communications interface module 13, the serial peripheral interface unit 14, and the multi-channel buffered serial port 15 are coupled as shown in FIG. 1. The analog to digital converter module 26, the encoder interface module 27, the event manager module 28 and the signal transition capture modules 29 are also coupled to the device peripheral interface bus 5 as shown in FIG. 1. These modules receive signals from sensor/encoder apparatus (not shown) monitoring external component (not shown). However, the implementation of the analog to digital converter module 26, the encoder interface module 27, the event manager module 28, and the signal transition capture module 29 are implemented differently than their counterparts in FIG. 1. In addition, inter-module control unit 20 has coupled thereto a bus 26A from analog to digital converter module 26, a bus 27A from encoder interface module 27, a bus 28A from event manager module 28 and a bus 29A from signal transition capture module 29. The present invention includes bus 24 that receives signals from the inter-module control unit 20 and applies signals to analog to digital converter module 26, encoder interface module 27, event manager module 28 and signal transition capture module 29.

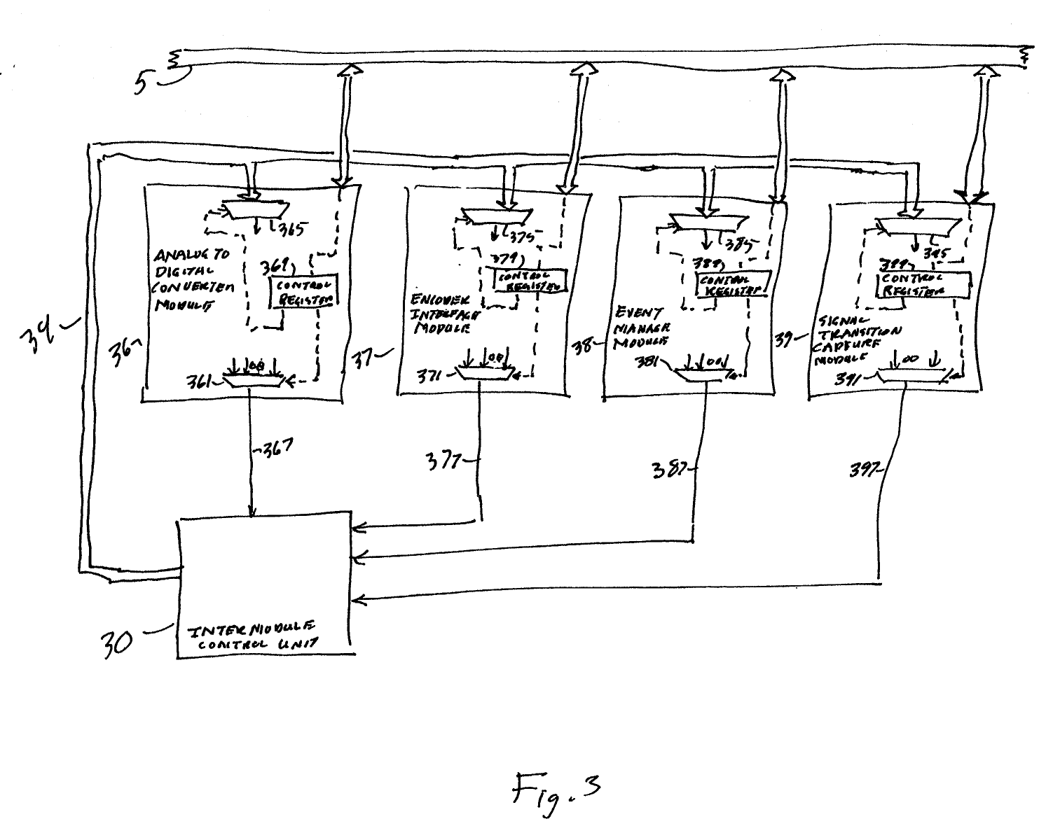

Referring to FIG. 3, a first embodiment of the inter-event controller unit 30 and associated apparatus, illustrating the operation of the present invention is shown. Each module, i.e. the analog to digital converter module 36, the encoder interface module 37, the event manager unit 38, and the signal transition capture module 39, generate a signal in response to a selected event within the module. The analog to digital converter module 36 has a conductor 367 coupled to a multiplexer 361, encoder interface module 37 has a conductor 377 coupled to multiplexer 371, event manage module 38 has a conductor 387 coupled to multiplexer gate 381, and signal transition capture module 39 has a conductor 397 coupled to a multiplexer 391. Each of the multiplexers has a control signal applied thereto, the control signal determining when a signal generated within the module is applied to the coupled conductor. The multiplexers 361, 371, 381 and 391 can have a plurality of signals applied thereto. Each of the conductors 367, 377, 387 and 397 are coupled to inter-module control unit 30. In inter-module controller 30, the conductors are assembled into an inter-module control bus 34. The inter-module control bus 34 applies the conductors to multiplexer 365 of the analog to digital converter module 36, to multiplexer 375 of the encoder interface module 37, to multiplexer 385 of the event manager module 38, and to multiplexer 395 of the signal transition capture module 39. The signals applied to the output terminal of the module can be applied to the input multiplexer of the same module. For example, the signal from the encoder interface module 37 output multiplexer 371 can be applied to the encoder interface module 73 input multiplexer 375. The control signals applied to the module input multiplexer can be used to prevent the signal from being entered in the module issuing the signal when desired by the user. Selected signals from each module can therefore be applied to all the modules. It will be further clear that a plurality of signals can be developed within each interface module and the output multiplexer is used to select, by means of control signals applied to the output multiplexer, the particular signal to be applied to the inter-module control unit 30. Also shown with each module is a control register, e.g., control register 369 is included in analog to digital converter module 36. The control registers 369, 379, 389, and 399 are accessible to the central processing unit via the system bus 5. The selection of the transmission of the signal through the module output multiplexers 361, 371, 381, and 391 and the signal selection by the module input multiplexer 365, 375, 385, and 395 are determined by the contents of the control register 369, 379, 389, and 399, respectively. In this manner, the inter-module transfer of signals is programmable and is controlled by the central processing unit. As will be clear, in systems in which only one internal signal is generated in an interface module, the output multiplexer can be replaced by a gate element.

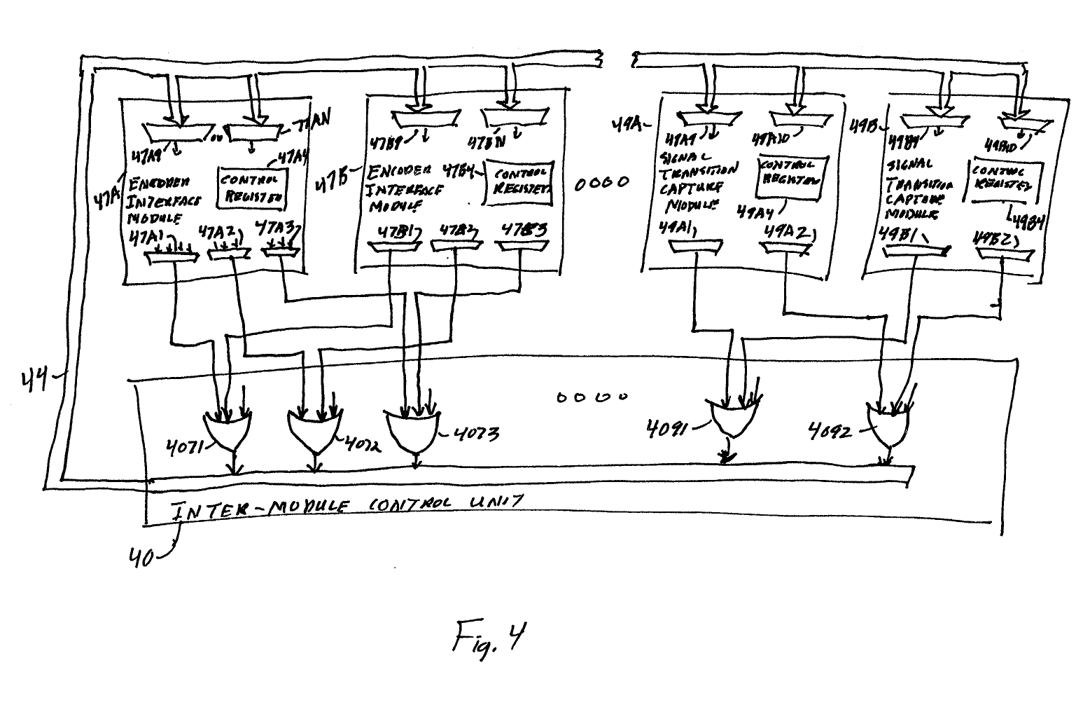

Referring to FIG. 4, a second and more complex embodiment of the present invention is illustrated. The embodiment illustrated in FIG. 3 has been generalized in three ways. First, a plurality of each type of module can be present. For example, in FIG. 4, two encoder interface modules 47A and 47B are shown. The plurality of interface modules can be necessary when the input or output signals of a single module cannot accommodate the number of signals required by the system. Second, because each module can have the ability to generate a plurality of signals, each signal indicating the presence of different selected status/event, each module can have a more than one output multiplexer. For example, in FIG. 4, each encoder interface module 47A and 47B has three conductors (from three multiplexers) applied to the interface control module 40, while each signal transition capture module 49A and 49B has two conductors (from two multiplexers) coupled to the inter-module control unit 40. Each encoder interface module 47A and 47B can generate the same status/event signals. Each encoder interface module 47A and 47B can also be implemented such that the associated control register, 47A4 and 47B4, respectively, can be programmed to transmit different status/event signals to the output terminals of the output multiplexers 47A1, 47A2, and 47A3, and 47B1, 47B2, and 47C3. Similarly, the two encoder interface modules 49A and 49B are coupled to the inter-module controller unit 40. Each encoder interface module 49A and 49B can generate two status/event signals. In encoder interface unit 49A, for example, these two status/event signals are applied to output terminals of multiplexers 49A1 and 49A2 as determined by control signals from control register 49A4. In the inter-module control unit 40, a logic “OR” gate is provided for each of the three status/event signals generated in encoder interface modules 47A and 47B. These logic “OR” gates in the inter-module control unit are logic “OR” gate 4071, logic “OR” gate 4072, and logic “OR” gate4073. The output terminal of multiplexer 47A1, the output terminal of multiplexer 47B1 are each coupled to an input terminal of logic “OR” gate 4071. The output terminal of multiplexer 47A2 and the output terminal of multiplexer 47B2 are each applied to an input terminal of logic “OR” gate 4072. The output terminal of multiplexer 47A3 and the output terminal of multiplexer 47B3 are each applied to an input terminal of logic “OR” gate 4073. Conductors coupled to the output terminals of logic “OR” gates 4071, 4072, and 4073 form part of the inter-module control bus 44. Similarly, in FIG. 4, two signal transition capture modules 49A and 49B are illustrated. Each of the signal transition capture modules 49A and 49B generates two status/event signals. The two status/event signals in signal transition capture unit 49A are applied to gate 49A1 and to 49A2, respectively. The two status/event signals generated in signal transition capture module 49B are applied to gates 49B1 and 49B2 respectively. Each of the two status/event signals generated in signal transition capture module 49A and in the signal transition capture module 49B have a logic “OR” gate in the inter-module control unit associated therewith. The output terminal of gate 49A1 of signal transition capture module 49A and the output terminal of gate 49B1 of signal transition capture module 49B are each coupled to an input terminal of logic “OR” gate 4091. The output terminal of gate 49A2 of event capture module 49A and the output terminal of gate 49B2 of gate 49B are each coupled to an input terminal of logic “OR” gate 4092. The output terminals of logic “OR” gates 4091 and 4092 are coupled to conductors that form part of the inter-module control bus 44. The third generalization is that each of the interface modules can have more than one input multiplexer. The inter-module control bus 44 is coupled to input terminals of multiplexers 47A9 through 47AN of the encoder interface module 47A, to input terminals of multiplexers 47B9 through 47BN of encoder interface module 47A, to input terminals of multiplexers 49A9 and 49A10 of signal transition capture module 49A, and to input terminals of multiplexers 49B9 through 49B10 of signal transition capture module 49B. The output terminals of the logic “OR” gates will also be coupled to the modules that are not explicitly shown in FIG. 4. As a practical matter, the analog to digital converter module(s) have the most frequent need for more than one input multiplexer.

As will be clear, the configuration shown in FIG. 4 is exemplary. Additional or different interface modules can be used with the inter-module control unit. Additional or fewer status/event signals can be generated in each module and applied to the intermodule control unit.

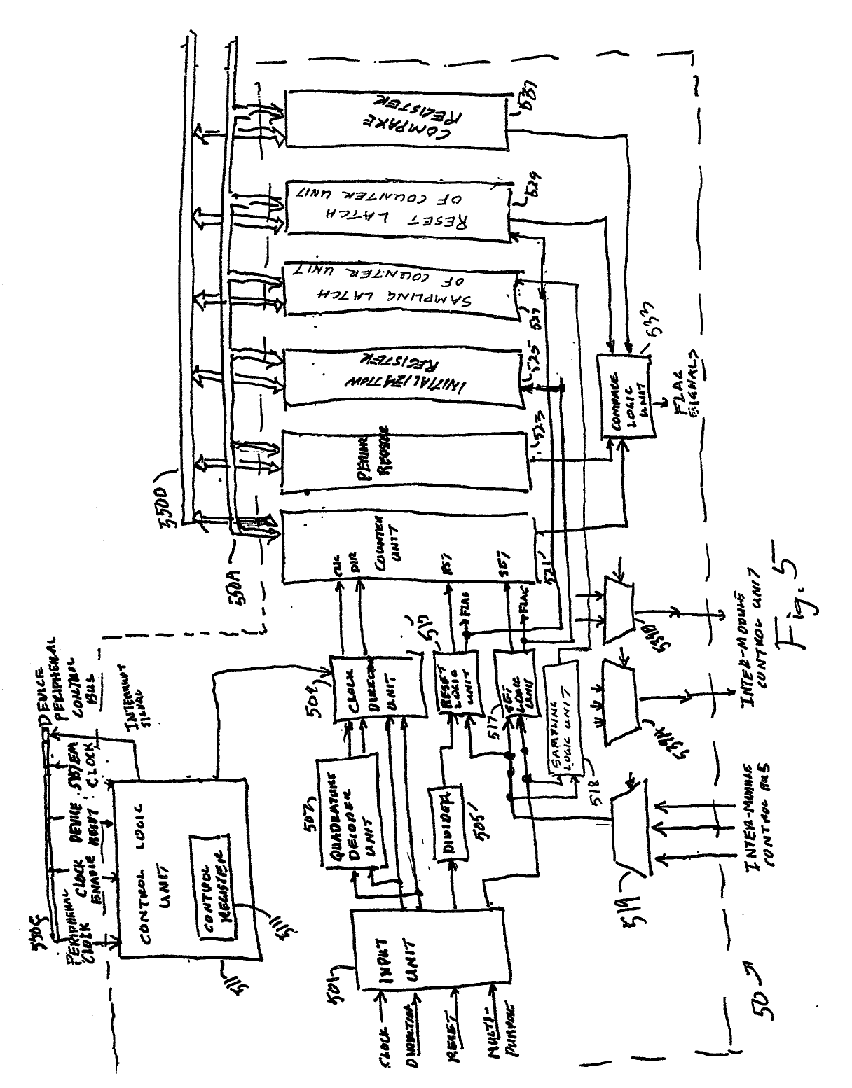

Referring to FIG. 5, a block diagram of the encoder interface module 50, according to the present invention, is shown. The encoder interface unit 50 includes an input unit 501. The input unit 501 receives input data signals from a sensor/encoder unit (i.e., the optical encoder of FIG. 1B) and serves the function of edge/polarity control. The input signals can include clock signals, direction signals, encoder index/reset signals, and multi-purpose signals. The input unit 501 applies signals to the quadrature decoder unit 507, the clock direction unit 509, divider 505, sampling logic unit 518, and set logic unit 517. The quadrature decoder unit 507 applies signals to clock direction unit 509. The encoder interface module 50 receives signals from the central processing unit on the device peripheral control bus 550C, the signals being applied to control unit 511. Signals applied to the control logic unit 511 include peripheral clock signal, peripheral clock enable signals, device reset signals, and system clock signals. The system clock signal is the clock to which all register accesses are synchronized. The peripheral clock signal is derived from the system clock signal by means of a programmable clock divider unit (not shown). The peripheral clock signal drives the timing of the logic in the encoder interface module. The control logic unit 511 includes all control logic (not shown) such as register read and write apparatus, flag setting and resetting apparatus, interrupt generation apparatus, etc. The control logic 511 applies peripheral clock signals, among other signals, to the clock direction unit 509 and applies an interrupt signal to the device peripheral control bus 550C. The divider 505 applies signals to the reset logic unit 515. Inter-modular event signals from the inter-module control bus are applied to the input multiplexer(s) 519. The output signals from the input multiplexer unit 519 are applied to reset logic unit 515, to the set logic unit 517, and to sampling logic unit 518. The clock direction logic unit 509 applies signals to the CLK and DIR terminals of counter unit 521, the reset logic unit 515 applies reset signals to the RST terminal of counter 521, and the set logic unit 517 applies set signals to SET terminal of counter unit 521. The clock/direction logic unit 509 (which includes the clock formation unit), the reset logic unit 515, and the set logic unit 517 can generate flags that are then stored in the control register 5111 of the control logic unit 511. The encoder interface module 50 also includes a period register 523, an initialization register 525, a sampling latch 527, a reset latch 529, and a compare register 531. The counter unit 521, the period register 523, the initialization register 525, the sampling latch 527, the reset latch 529, and the compare register 531 receive address signals from the device peripheral address bus 550A and exchange data signals with the device peripheral data bus 550D. The reset logic unit 515 applies signals to the reset latch 529 and the set logic unit 517 applies signals to the initialization latch 525. The sampling logic unit 518 applies signals to the sampling latch. The counter unit 521, the period register 523, reset latch 529, and compare register 531 apply signals to compare logic unit 533. Compare logic unit 533 generates flag signals that can be stored in the control register 5111. Multiplexer 539A and multiplexer 539B receive signals from selected portions of the encoder interface module 50 in response to preselected conditions and apply signals selected by control signals to the inter-module control unit.

2. Operation of the Preferred Embodiment

The typical outputs of a quadrature optical encoder coupled to a rotating shaft are two pulse trains. The two signals are directly applied to the clock and direction input terminals of the input unit. These two signal channels are pulse trains with a 50% duty cycle, 90 degrees out of phase. The quadrature decoder unit 507 decodes the signal pulses into a clock signal and a direction signal. The frequency of the clock signal represents the speed of the shaft rotation. The direction signal represents the direction of the shaft rotation. The clock output from the quadrature decoder unit 207 counts the high-to-low and the low-to-high transitions on both channels as they are detected. The direction signal from the sensor indicates the direction of the shaft rotation and determines whether the counter register should count up or down on the detection of a transition in either of the two channels. Because the input clock and direction signals are 90 degrees out of phase, the detection of a simultaneous transition results in an error signal. Optionally, the signals applied to the clock and direction input terminals can be directly applied to the CLK and DIR terminals of the counter. In this case, the count is at the rate of the clock signal in the direction of the direction input. The counter can also optionally use the device peripheral clock as the clock source, thus becoming a simple timer. The number in the counter can be initialized by the value in the initialization register in response to a selected trigger. The number in the counter can also be latched into the sample or reset latches in response to appropriate trigger signals. The initialization, reset, and sample trigger signals can be the reset and multi-purpose input signals or can be inter-module events. A divide value can be applied to the reset input such that the counter is reset to zero only after a preselected number of reset pulses has been received. Every time a reset of the counter occurs, the value in the counter is written to the reset latch. An interrupt can be generated if the latched value is not zero. The number in the counter can be compared with the value in the period register or the compare register or to zero. When a period match is detected, the counter can either rollover to zero or continue counting. The central processing unit has access to the counter and the registers. When the signal used as a trigger of the sample latch is periodic, the difference (or delta) of the latched contents becomes a measurement of the number of counts (or pulses) per fixed length of time. This difference is a direct indication of pulse frequency or the speed/frequency of shaft rotation.

As indicated in FIG. 1B, three conductors representing three signals are coupled from the encoder unit. In addition to the two out-of-phase pulse trains, an index pulse signal is provided to the encoder interface module. The index pulse signal marks a known angular position of the shaft. This index pulse signal can be directly coupled to the index/reset terminal of the encoder interface module. When enabled, this input signal can cause the counter to reset to zero when an encode index pulse is identified. Therefore, the counter can be brought into alignment with a known angular position of the shaft. Optionally, the encoder interface module index/reset divider (505) can be programmed to cause a counter reset for a selected number of encoder index pulses.

The encoder interface module includes multiplexers that can select signals from other modules coupled to the device peripheral bus and can select signals from the encoder interface module to be applied to the other modules. In this manner, signals can be exchanged between the interface modules and activity of the modules can be coordinated without the intervention of the central processing unit. The signals controlling the transmission of signal through the multiplexer can be programmed during initialization, i.e., by the central processing unit.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. An encoder interface module comprising:
an input unit for receiving input signals from an encoder unit;
a counter unit coupled to the input unit for counting the input signals;
a plurality of registers; and
a compare unit, the compare unit coupled to the selected registers and the counter unit, the compare unit generating flag signals in response to first control signals when a value in the counter unit and a value in a register have predetermined relationship, the compare unit generating flag signals in response to second control signals when the value of the counter unit is zero.

2. The encoder interface module as recited in claim 1 further comprising;
a control register, the control register storing the flag signals.

3. The encoder interface module as recited in claim 2 wherein the input signals are a series of pulse streams, the pulse streams determining clock signals and direction signals.

4. The encoder interface module as recited in claim 3 wherein the input signals include an encoder index/reset pulse.

5. The encoder interface unit as recited in claim 3 further including a quadrature decode unit, the quadrature decode unit determining the frequency and direction of counter increment or decrement.

6. The encoder interface unit as recited in claim 1, the encoder interface unit being coupled to a device peripheral bus, wherein other modules are coupled to device peripheral bus, the encoder interface unit further comprising an output multiplexer, the output multiplexer applying control signals generated in the encoder interface to the modules.

7. The encoder interface unit as recited in claim 6, the encoder interface unit further comprising at least one input multiplexer unit for selecting a control signal from the modules to be distributed within the encoder interface unit.

8. The encoder interface unit as recited in claim 1 wherein the plurality of registers is selected from the group consisting of a period register, an initialization register, a sampling latch, a reset latch, and a compare register.

9. The encoder interface unit as recited in claim 1 wherein the signals applied to the encoder interface unit are derived from a rotating shaft.

10. The encoder interface unit as recited in claim 9 wherein the encoder interface unit derives a quantity related to the speed/frequency of the shaft rotation.

11. A method for providing an encoder interface unit between an encoder unit and a central processing unit, the method comprising:
in response to applied signals from an encoder unit, generating pulses derived from the applied signals;
counting the number of pulses;
comparing the number of pulses with a preselected value; and
generating a flag signal when the number of pulses and the preselected value have predetermined relationship.

12. The method as recited in claim 11 wherein the preselected value is selected from the group of preselected values consisting of period value, a zero value, and a compare value.

13. The method as recited in claim 11 wherein the generated pulses includes determining a direction of rotation from the applied signals.

14. The method as recited in claim 11 further comprising selecting a control signal for distribution to other modules without the intervention of the central processing unit.

15. The method as recited in claim 11 further comprising selecting a control signal from the interface units for determining the use of the interface unit as a reset trigger and a sample latch trigger.

16. The method as recited in claim 11 wherein counting the number of pulses provides a quantity related to the speed/frequency of a rotating shaft.

17. A data processing unit comprising:
a central processing unit;
a device peripheral bus; and
a plurality of peripheral devices coupled to the device peripheral bus, wherein one of the peripheral devices is an encoder interface module; the encoder interface module including:
an input unit for receiving input signals from an encoder unit;
a counter unit coupled to the input unit for counting the input signals;
a plurality of registers; and
a compare unit, the compare unit coupled to the selected registers and the counter unit, the compare unit generating flag signals when a value in the counter unit is zero or the value in the counter and a value in a register have a predetermined relationship.

18. The data processing system as recited in claim 17 wherein the encoder interface module further includes a control register, the control register storing the flag signals.

19. The data processing system as recited in claim 17 further comprising:
at least one additional peripheral device coupled to the device peripheral bus;
an inter-module bus; and
an inter-module control unit, wherein the encoder interface unit further includes
an input multiplexer for selectively transmitting signals from the inter-module bus to the encoder interface unit, and
an output multiplexer for selectively transmitting signals from the encoder interface module to the inter-module control unit.

20. The data processing system as recited in claim 19 wherein the inter-module control unit and the inter-module bus transfer control signals between interface modules without intervention of the central processing unit.

21. The data processing system as recited in claim 20 wherein the additional peripheral device is selected from the group consisting of an analog to digital converter module, an encoder event manager module, and an event capture module.

22. The data processing system as recited in claim 17 wherein the counter unit and the registers of the encoder interface module are coupled to the device peripheral bus.

23. The data processing system as recited in claim 17 wherein the value in the counter unit is related to the speed/frequency of a shaft.

24. The data processing system as recited in claim 17 wherein the signals from the encoder unit include two pulse streams and an index reset/signal.
